(19) United States
(12) Patent Application Publication
(10) Pub. No.: US 2015/0350502 A1
(43) Pub. Date: Dec. 3, 2015

(54) WAFER-LEVEL CAMERA MODULE AND MANUFACTURING METHOD THEREOF

(71) Applicant: ALTEK CORPORATION, HSINCHU (TW)

(72) Inventor: Shu-Yu LIN, New Taipei City (TW)

(21) Appl. No.: 14/328,057

(22) Filed: Jul. 10, 2014

(30) Foreign Application Priority Data
May 30, 2014 (TW) 103118977

(51) Int. Cl. H04N 5/225; H04N 5/232; H05K 13/04; H04N 5/335

(52) U.S. Cl. CPC H04N 5/2254; H04N 5/335; H04N 5/23241; H05K 13/0478

(57) ABSTRACT

The present disclosure illustrates a wafer-level camera module for an endoscope and manufacturing method thereof. The wafer-level camera module includes substrate, image sensor unit, light emitting units, lens module, and transparent package member. The substrate has a first area and a plurality of second areas. The image sensor unit and the light emitting units are located at the first area and the plurality of second areas, respectively. The image sensor unit is covered by the lens module, but the plurality of light emitting units are not covered by the lens module. The transparent package member is disposed above the plurality of plurality of light emitting units and around the lens module. The light generated from the light emitting units transmits through the transparent package to outer environment. An opaque material is coated between the lens module and the transparent package member.

### CROSS-REFERENCE TO RELATED APPLICATION

This application claims the benefit of Taiwan Patent Application No. 103118977, filed on May 30, 2014, in the Taiwan Intellectual Property Office, the disclosure of which is incorporated herein in its entirety by reference.

### BACKGROUND OF THE INVENTION

1. Field of the Invention

The present disclosure relates to a camera module and manufacturing method thereof, in particular, to a wafer-level camera module applied to an endoscope and manufacturing method thereof.

2. Description of the Related Art

An endoscope is a long and flexible tube apparatus and mainly includes an image capture device and a light source. After the endoscope is connected to a displayer, organs in human's body, inner sight of a vehicle, components within an electronic device, or cracks of building structure can be imaged by the endoscope and then shown on the displayer. The endoscope can be applied in application of industry and medical treatment. When the organs inside the body gets hurt or a tool component is damaged, the endoscope can be utilized to inspect so long as a channel exists between the organ or the damaged tool component and the outside. For example, an endoscope for upper digestive tract such as esophagus, stomach and duodenum, it is inserted through the oral cavity. A colonoscopy is inserted through the anus. An endoscope for a turbine blade is inserted through an exhaust port.

As miniaturization for the lens and the light emitting unit are developed maturely, new endoscope has the lens and the light source disposed at the front end thereof, and the front end including the lens and the light source is inserted inside the body. A cover glass is covered on an outer layer of the front end to prevent the lens or the light source from dropping off. However, based on light reflection principle, light emitted from the light source is possibly reflected by the cover glass and enters to the image sensor unit, which results in a white spot effect in the captured image.

In addition, in a traditional manufacturing process of a lens module of the endoscope, the lens and the image sensor are produced separately fist, and then the lens and the image sensor are performed focusing correction and welded by a packaging company. A series of testing process are performed after the packaging is completed, so the processes are complex and time-consumptive, and some extra components may be used on the lens module of the endoscope. Moreover, after each lens module is corrected, different misalignments may exist between the lens modules so consistency between products is lacked.

Therefore, what is need is a wafer-level camera module to solve the above-mentioned problems.

### SUMMARY OF THE INVENTION

An aspect of exemplary embodiments of the present disclosure directs to a wafer-level camera module for an endoscope and manufacturing method thereof capable of avoiding occurrence of white spot during image capture, so as to improve quality of captured image.

An aspect of exemplary embodiments of the present disclosure directs to a wafer-level camera module for an endoscope and manufacturing method thereof capable of preventing from disposing redundant element on the lens and the image sensor unit, so that efficient structure configuration can be achieved.

An aspect of exemplary embodiments of the present disclosure directs to a wafer-level camera module for an endoscope and manufacturing method thereof, so the misalignment caused during traditional assembly of the lens and the image sensor unit on the endoscope can be prevented by disposing a wafer-level lens on the endoscope, the yield rate can be improved correspondingly.

An exemplary embodiment of the present disclosure provides a wafer-level camera module including a substrate, an image sensor unit, a plurality of light emitting units, a lens module and a transparent package member. The substrate has a first area, a plurality of second areas located around the first area, and a plurality of conductive connectors. The image sensor unit is disposed on the first area. The plurality of light emitting units are disposed on the plurality of second areas. The plurality of conductive connectors of the substrate connect electrically the image sensor unit with the plurality of light emitting units, and the plurality of conductive connectors receive electric power from outside to provide driving power to the image sensor unit and the plurality of light emitting units. The lens module includes at least one optical element, and the lens module covers the image sensor unit but not covers the plurality of light emitting units. The transparent package member is disposed above the plurality of light emitting units and around the lens module. The light generated from the plurality of light emitting units transmits through the transparent package to the outer environment. The opaque material is coated between the lens module and the transparent package member.

Preferably, at least one optical element includes at least one lens or an infrared cut-off filter.

Preferably, the transparent package member includes light scattering particles to scatter the light generated from the plurality of light emitting units.

Preferably, each of the plurality of light emitting units includes a light emitting diode.

Preferably, a light guide plate is disposed between the light emitting diode and the transparent package member.

An exemplary embodiment of the present disclosure provides a manufacturing method for wafer-level camera module, and the method includes following steps: providing an image sensor unit and a plurality of light emitting units, the plurality of light emitting units being around the image sensor unit; disposing a substrate on a tin plate, disposing a plurality of conductive connectors under the tin plate, and disposing the image sensor unit and the plurality of light emitting units on the substrate; covering a transparent cover on the image sensor unit and the plurality of light emitting units to form a first package unit; disposing the lens module and the transparent package member on the first package unit, the transparent package member being above the plurality of light emitting units and around the lens module, lens module being above the image sensor unit but not covering the plurality of light emitting units.

Preferably, the lens module includes at least one lens or an infrared cut-off filter.

Preferably, the method further includes a step of coating an opaque material between the lens module and the transparent package member, and each of the plurality of light emitting units includes a light emitting diode.

Preferably, the method further includes a step of disposing a light guide plate between the light emitting diode and the transparent package member. Each of the plurality of light emitting units includes a light emitting diode.

### BRIEF DESCRIPTION OF THE DRAWINGS

The detailed structure, operating principle and effects of the present disclosure will now be described in more details hereinafter with reference to the accompanying drawings that show various embodiments of the present disclosure as follows.

FIG. 1 is a schematic view of an exemplary embodiment of a wafer-level camera module of the present disclosure.

FIG. 2 is a top view of the exemplary embodiment of the wafer-level camera module of the present disclosure.

FIG. 3 is a schematic view of an exemplary embodiment of an endoscope installed with the wafer-level camera module of the present disclosure.

FIG. 4 is a flow diagram of the exemplary embodiment of a manufacturing method for the wafer-level camera module of the present disclosure.

FIG. 5 is a schematic view of the exemplary embodiment of the manufacturing method for the wafer-level camera module of the present disclosure.

### DETAILED DESCRIPTION OF THE PREFERRED EMBODIMENTS

Reference will now be made in detail to the exemplary embodiments of the present disclosure, examples of which are illustrated in the accompanying drawings. Therefore, it is to be understood that the foregoing is illustrative of exemplary embodiments and is not to be construed as limited to the specific embodiments disclosed, and that modifications to the disclosed exemplary embodiments, as well as other exemplary embodiments, are intended to be included within the scope of the appended claims. These embodiments are provided so that this disclosure will be thorough and complete, and will fully convey the inventive concept to those skilled in the art. The relative proportions and ratios of elements in the drawings may be exaggerated or diminished in size for the sake of clarity and convenience in the drawings, and such arbitrary proportions are only illustrative and not limiting in any way. The same reference numbers are used in the drawings and the description to refer to the same or like parts.

It will be understood that, although the terms ‘first’, ‘second’, ‘third’, etc., may be used herein to describe various elements, these elements should not be limited by these terms. The terms are used only for the purpose of distinguishing one component from another component. Thus, a first element discussed below could be termed a second element without departing from the teachings of embodiments. As used herein, the term “or” includes any and all combinations of one or more of the associated listed items.

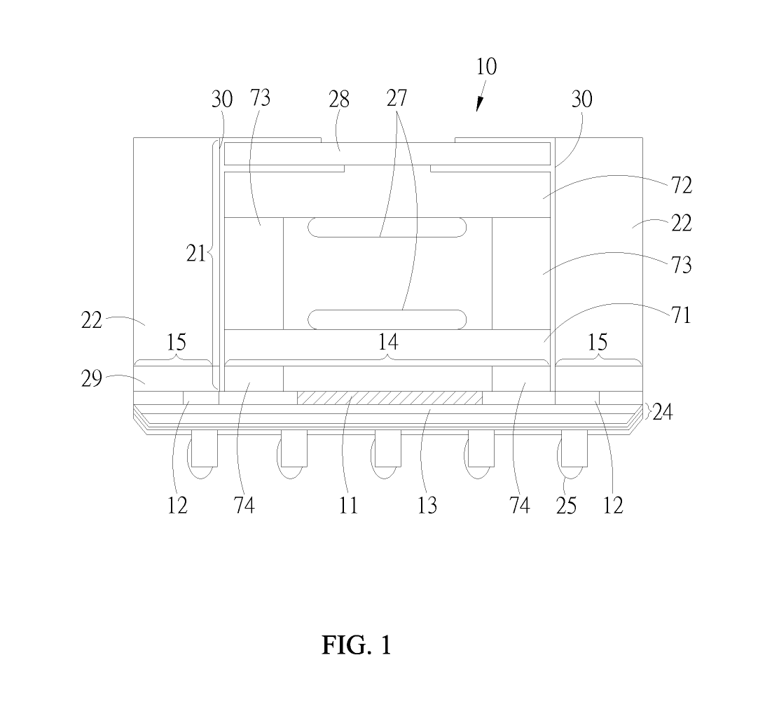

Please refer to FIG. 1 which shows a schematic view of an exemplary embodiment of a wafer-level camera module according to the present disclosure. The wafer-level camera module 10 includes a substrate 13, an image sensor unit 11, a plurality of light emitting units 12, a lens module 21, and a transparent package member 22. For example, the image sensor unit 11 includes a charge coupled device or a CMOS Image sensor device. The light emitting unit 12 includes a light emitting diode. The transparent package member 22 includes a transparent resin. The lens module 21 includes at least one lens 27.

The substrate 13 includes a first area 14 and a plurality of second areas 15 thereon, and the plurality of second areas 15 are located around the first area 14. The image sensor unit 11 is disposed on the first area 14. The plurality of light emitting units 12 are disposed on the plurality of second area 15, respectively. In implementation, the substrate 13 is connected with a tin plate 24 thereunder, and the tin plate 24 includes a plurality of conductive connectors 25 thereunder. The plurality of conductive connectors 25 connect electrically the image sensor unit 11 with the plurality of light emitting units 12 to a printed circuit board (not shown in FIGs) and can receive electric power from outside to provide driving power to the image sensor unit 11 and the plurality of light emitting units 12.

The lens module 21 can be a wafer-level lens module which include glass wafer 71 and 72, lens 27, and spacer 73 and 74. In addition, the lens module 21 further includes an infrared cut-off filter 28.

The lens module 21 is disposed above the image sensor unit 11 by the spacer 74, but not covers the plurality of light emitting units 12. The transparent package member 22 is disposed above the plurality of light emitting units 12 and around the lens module 21. In implementation, the transparent package member 22 can serve as a light guide, the light generated from the plurality of light emitting units 12 is transmitted to outside via the transparent package member 22.

An opaque material 30 is coated between the lens module 21 and the transparent package member 22, to prevent the light generated by the light emitting units 12 from impairing the imaging of the image sensor unit 11.

In addition, a light guide plate 29 can be disposed between the light emitting units 12 and the transparent package member 22. For example, the light guide plate 29 can be a package resin including phosphor, so the light guide plate 29 can covert the light generated form the light emitting unit 12 to other color light, such as white light, for different design requirement.

The transparent package member 22 can further includes light scattering particles (not shown in FIGs) to scatter the light generated from the light emitting units 12, to provide better light source while the lens module 21 captures image. The lens module 21 is integeratdly mounted on a surface of the image sensor unit 11. The image sensor unit can include a CMOS image sensor or a CCD. The transparent package member 22 can include high transparent resin, such as epoxy resin or silicone, so that the light emitted from the light emitting units 12 can penetrate through the transparent package member 22 to outside.

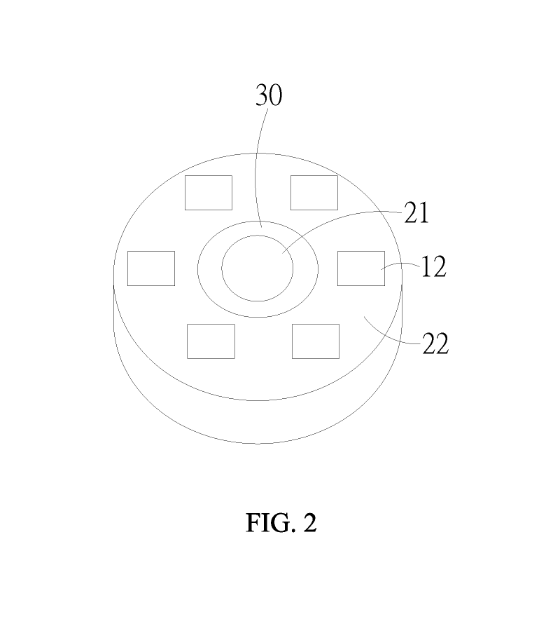

Please refer to FIG. 2 which shows a top view of an exemplary embodiment of a wafer-level camera module of the present disclosure. The plurality of light emitting units 12 are arranged annularly in the transparent package member 22, to provide a uniform and dispersed light source. The lens module 21 and the transparent package member 22 are separated by the opaque material 30.

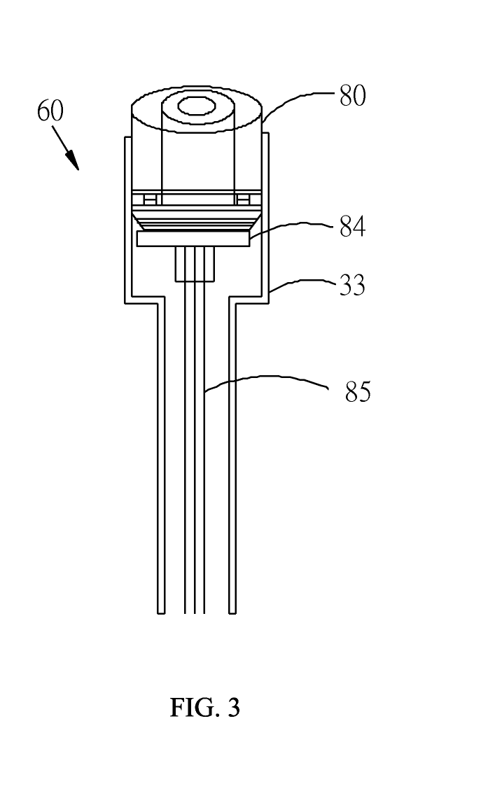

Please refer to FIG. 3 which shows an endoscope including an exemplary embodiment of the wafer-level camera module of the present disclosure. As shown in FIG. 3, the endoscope 60 includes a wafer-level camera module 80 and hollow tube 33. The wafer-level camera module 80 is disposed at a front end of the hollow tube 33, and the outer layer of the hollow tube 33 is covered by flexible composite material. In implementation, the wafer-level camera module 80 is connected electrically with a printed circuit board 84 and a plurality of optical fibers 85 thereunder, whereby the image signal can be transmitted to a display end (not shown in FIGs).

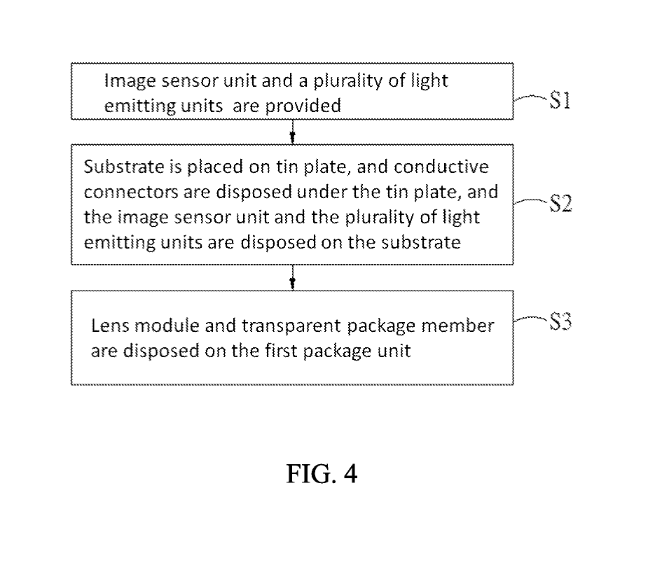

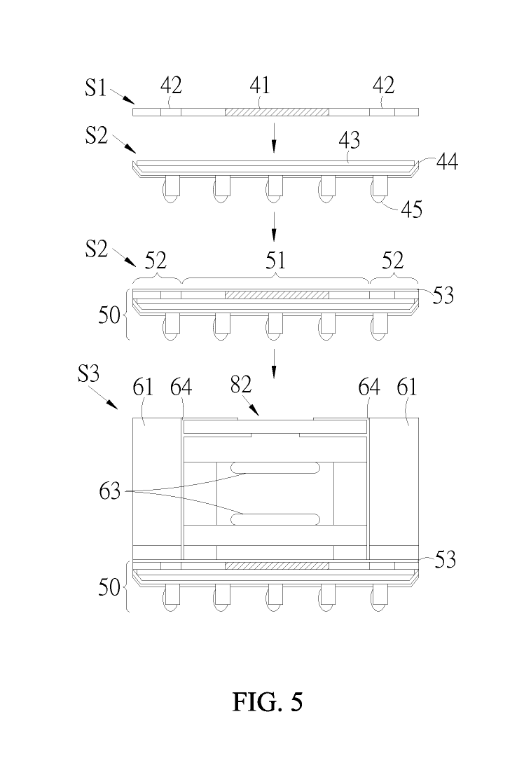

Please refer to both of FIG. 4 and FIG. 5 which are flow diagram and schematic view of the exemplary embodiment of a manufacturing method for the wafer-level camera module of the present disclosure. The manufacturing method includes following steps.

In step S1, an image sensor unit 41 and a plurality of light emitting units 42 are provided.

In step S2, a substrate 43 is placed on a tin plate 44, and a plurality of conductive connectors 45 are disposed under the tin plate 44, and the image sensor unit 41 and the plurality of light emitting units 42 are disposed on the substrate 43. A transparent cover 53 on the image sensor unit 41 and the plurality of light emitting units 42 is covered to form a first package unit 50. The image sensor unit 41 is disposed on a first area 51 of the substrate 43, and the plurality of light emitting units 42 are disposed on a plurality of second areas 52 of the substrate 43.

In step S3, a lens module 82 and a transparent package member 61 are disposed on the first package unit 50. The transparent package member 61 is located above the plurality of light emitting units 42 and around the lens module 82. The lens module 82 is disposed above the image sensor unit 41. As shown in FIG. 5, the lens module 82 includes at least one lens 63, and an opaque material 64 is coated between a transparent package member 61 and the lens module 82.

In summary, the manufacturing method for the wafer-level lens of the present disclosure is performed without using the cover glass, so the white spot problem caused by the cover glass during image capture can be prevented, and the quality of captured image can be improved. In addition, extra components mounted on the lens and image sensor unit can be reduced by using the packaging process, so an efficient structure arrangement can be achieved, and the misalignment caused during traditional assembly of the lens and the image sensor on the endoscope can also be reduce for improving the yield rate.

The above-mentioned descriptions represent merely the exemplary embodiment of the present disclosure, without any intention to limit the scope of the present disclosure thereto. Various equivalent changes, alternations or modifications based on the claims of present disclosure are all consequently viewed as being embraced by the scope of the present disclosure.

What is claimed is:

1. A wafer-level camera module, comprising:
a substrate, having a first area, a plurality of second areas located around the first area and a plurality of conductive connectors;
an image sensor unit, disposed on the first area;
a plurality of light emitting units, disposed on the plurality of second areas, wherein the plurality of conductive connectors of the substrate electrically connect the image sensor unit with the plurality of light emitting units, and the plurality of conductive connectors receive electric power from outside to provide driving power to the image sensor unit and plurality of light emitting units;
a lens module, including at least one optical element, the lens module covering the image sensor unit but not covering the plurality of light emitting units; and
a transparent package member, disposed above the plurality of light emitting units and around the lens module, the light generated from the plurality of light emitting units transmitting through the transparent package to the outside;
wherein, an opaque material is coated between the lens module and the transparent package member.

2. The wafer-level camera module according to claim 1, wherein the at least one optical element comprise at least one lens and/or an infrared cut-off filter.

3. The wafer-level camera module according to claim 1, wherein the transparent package member comprises light scattering particles to scatter the light generated from the plurality of light emitting units.

4. The wafer-level camera module according to claim 1, wherein each of plurality of light emitting units comprises a light emitting diode.

5. The wafer-level camera module as defined in claim 4, further comprising a light guide plate disposed between the light emitting diode and the transparent package member.

6. A manufacturing method for wafer-level camera module, comprising:
providing an image sensor unit and a plurality of light emitting units;
disposing a substrate on a tin plate, disposing a plurality of conductive connectors under the tin plate, disposing the image sensor unit and the plurality of light emitting units on the substrate, the plurality of light emitting units located around the image sensor unit;
covering a transparent cover on the image sensor unit and the plurality of light emitting units to form a first package unit; and
disposing a lens module and a transparent package member on the first package unit, the transparent package member being above the plurality of light emitting units and around the lens module, the lens module being above the image sensor unit but not covering the plurality of light emitting units.

7. The manufacturing method according to claim 6, wherein the lens module comprise at least one lens and/or an infrared cut-off filter.

8. The manufacturing method according to claim 6, further comprising:
coating an opaque material between the lens module and the transparent package member, wherein each of the plurality of light emitting units comprises a light emitting diode.

9. The manufacturing method according to claim 6, further comprising:
disposing a light guide plate between the light emitting diode and the transparent package member, wherein each of the plurality of light emitting units comprises a light emitting diode.
